(19) United States
(12) Patent Application Publication
(10) Pub. No.: US 2007/0089983 A1
(43) Pub. Date: Apr. 26, 2007

(54) CATHODE INCORPORATING FIXED OR ROTATING TARGET IN COMBINATION WITH A MOVING MAGNET ASSEMBLY AND APPLICATIONS THEREOF

(75) Inventors: Dean Plaisted, Kennebunk, ME (US); Alan Plaisted, Swanton, VT (US)

Correspondence Address: MESMER & DELEAULT, PLLC, 1 NEW HAMPSHIRE AVE., SUITE 125, PORTSMOUTH, NH, 03801, US

(73) Assignee: SOLERAS LTD., Biddeford, ME (US)

(21) Appl. No.: 11/552,270

(22) Filed: Oct. 24, 2006

Related U.S. Application Data
(60) Provisional application No. 60/596,824, filed on Oct. 24, 2005.

(51) Int. Cl. C23C 14/32; C23C 14/00

(52) U.S. Cl. 204/298.01; 204/192.1

(57) ABSTRACT

A sputtering cathode apparatus having a hollow cylindrical sputter target that is fixed or rotatable about its central axis and an internal magnet assembly that is rotated axially within the sputter target.

### BACKGROUND

1. Field of the Invention

The invention is in the field of physical vapor deposition cathodes.

2. Description of the Related Art

Physical vapor deposition can be accomplished in many ways. Fundamentally the process is performed in a vacuum environment with the possible introduction of specific gases to perform the desired deposition from a given source material or materials. Source materials can be evaporated, plasma arc deposited, sputter coated and other ways well known in the art of physical vapor deposition. In typical evaporative applications, components to be coated are loaded onto fixtures that hold the parts in the vacuum chamber. The chamber is closed and the atmosphere evacuated. A source material is typically heated through various techniques to the point where it is evaporated within the vacuum chamber thus coating the chamber and components fixtured within the chamber.

To improve uniformity and other properties, the component fixtures can be in motion about the source or sources of evaporation. In some processes other gases are introduced into the chamber as well to affect the coating properties. In typical sputter applications, a gas such as argon is introduced into the chamber and a cathode assembly is used to ionize the gas into a plasma and to locate that plasma in close proximity to the source material or target. This creates an efficient sputter process that can transfer the target material from the source target to items in the vacuum chamber that are desired to be coated. The cathode design and chamber configuration can affect the rate that items are coated with the desired film properties, the uniformity of the coatings, and the coating composition. In addition it is possible to have multiple sources and/or deposition techniques combined into a coating process within the vacuum chamber.

In evaporative applications, it may be desirable to have multiple evaporative sources to facilitate coating uniformity of parts located in a large chamber. This may typically increase the service and/or operator interaction to keep the process supplied with material for evaporation. Typical evaporative sources may include coils with which clips of the desired material to be evaporated are attached. These clips must be placed onto the coil assemblies every cycle and limit the ability for continuous processing. In addition it can be difficult to control the coating compositions when more than one material is desired to be coated in either simultaneous or sequenced coating operations.

There are many relative differences and subsequent advantages of different physical vapor deposition processes depending on the items to be coated, related physical properties, and the resultant properties after coating. In addition economics, environmental considerations, and coating properties/compositions also play roles in matching the right process to the desired application.

A large number of evaporative coating systems exist and are currently operating in the physical vapor deposition industry. In addition a large number of vacuum chambers are manufactured with sputtering cathodes of various sizes and configurations. These sputtering systems typically use planar type cathodes with planar target materials. Some systems are capable of using multiple evaporative sources or cathodes simultaneously or sequentially within a vacuum chamber to co-deposit materials or to layer them onto the item to be coated. In any application, the proximity of the item to be coated, its related fixturing, and its possible movement in relation to the source will affect the coating properties such as uniformity across the coating area.

It is desirable to utilize an efficient target source with high material utilization and long service intervals for the coating of components in a vacuum chamber. Utilization is achieved through the efficient use of as much target material as possible while service intervals can be extended by increasing the amount of target material available for deposition. It is also desirable to be able to control the direction of the coating material as it leaves the source surface and travels through the vacuum within the chamber until it ultimately coats whatever it strikes first, be it a fixture, chamber wall, shield, or the desired part to be coated. This is the reason why one finds elaborate part fixturing with planetary style motions together with multiple sources in some coating applications.

Through source location and part movement, the utilization of source material can be substantially improved. However, an evaporative source, arc source, or a cathode have emission patterns that are consistent and not readily altered during any given process except through the control of the rate of deposition by changing the heating and/or sputter power. It would be desirable to be able to focus the coating to coat preferentially in a particular direction and to be able to control that direction during the process. In addition, planar sputter target utilization is typically between 35% and 60% depending on the cathode and application. It is desirable to utilize as much of the source material as possible. Another benefit is increased process time between setups. This often saves more money than improved utilization of the target.

Rotary targets and related cathode configurations are well known in the glass and web coating industries. Applications have been developed for other types of products as well. A rotary cathode utilizes a fixed magnet assembly while a cylindrical target rotates around the magnet assembly. The magnetron effect of the magnet pack ensures that sputtering occurs on a limited surface of the rotating target and that target material is ejected from that target surface area. In this way a roll of material to be coated can be unspooled externally or internal to the vacuum chamber and can be coated when the material is passed by a rotary target that is sputtering in the material's direction. The same situation occurs when passing sheets of glass past the cathode. By rotating the cylindrical target around the central magnet bar, new target material is constantly being sputtered from the surface, giving higher utilization of a larger volume of material (cylindrical versus planar target) and longer time between target changes as the entire cylinder can be used for the sputtering process. In this way, rotary targets can attain significant advantages over planar cathode techniques.

In sputter applications using planar targets the deposition distribution is typically a Gaussian distribution that can be modified through magnetron design and/or target to coated substrate distance. It is also possible to arrange multiple sources to overlap their individual deposition distributions and superimpose them on one another. Utilizing any one or combinations of these methods can lead to more uniform or designed coatings regarding thickness profiles on a given coated component. A problem exists however that these solutions are typically designed using fixed hardware that is not readily reconfigured or changeable, especially during a process run of the equipment. It would be desirable to have a sputter source that could change the primary direction of its sputter deposition so that coating distributions could be changed, even during the process. It would also be desirable to change the essential characteristics of the magnet and/or magnet pack assembly during the process run.

In all coating applications, it is desirable to control the initial start of the deposition process until the steady state coating process has been achieved. This is commonly known as “burn-in”. Source material deposited during the burn-in process is not desirable to coat parts. It is usual practice to let material from the burn-in process coat chamber walls, shields, and transport components that are now exposed because the item to be eventually coated is not present. This leads to increased maintenance and cleaning requirements. It is desirable to have a source that can be burned-in while focusing the resultant deposition on a shield or chamber wall rather than on associated components within the chamber that are not intended to be coated.

### SUMMARY OF THE INVENTION

The invention is a cathode assembly using a fixed or rotating cylindrical target and a central magnet arrangement that can be rotated within the cylindrical target around the center of the cylindrical target's axis. The magnet arrangement creates a magnetron effect at the surface of the target and can be configured to sputter the target material in a linear area along the length of the cylindrical target, or be configured to sputter in multiple locations of the target depending on the design of the magnet pack assembly or assemblies. Multiple magnet bars can be assembled and arranged with offset lengths along the length of the cylindrical target or located at different radial locations around the inner circumference of the target. This allows complete control of the target areas to be sputtered and can control erosion of the target at any point of its surface to optimize the process characteristics and utilization of the target material.

In a rotary cathode typical of the related art, the linear magnet arrangement is fixed and aligned along the length of the cylindrical target. The target is rotated about its center axis around the magnet pack. The linear sputter area along the target length is constantly being replaced by a new section of the target, thus eroding the entire surface of the target uniformly. The emission area is unidirectional from the cylinder wall at the point determined by the fixed magnet bars. This is a good arrangement for coating objects passing by only one side of the target cylinder such as glass or web coating. In many existing applications as mentioned earlier, vacuum chambers and related fixturing of parts are designed and optimized for centrally located emission sources such as a torroidal planar target or an evaporative coil assembly. In these applications, a rotary cathode sputtering from one side only is not effective. The cathode design of this invention solves this problem by rotating the magnet assembly or assemblies around the inside of the target and moving the sputter area around the target in up to a full 360 degrees and/or in the desired direction for sputtering to occur. In applications where the magnet bars do not rotate continuously in a full revolution, the target can also be rotated to ensure full utilization of the target material. These and other features, aspects, and advantages of the present invention will become better understood with reference to the following description, drawings, and claims.

### DRAWINGS

FIG. 1A is a cross section of a cathode and target assembly according to the present invention, showing the chamber and work piece.

FIG. 1B is a side elevation of the invention of FIG. 1A.

FIG. 2 is an orthogonal view of the drive assembly.

FIG. 3 is an exploded view of the magnet assembly of the present invention.

FIG. 4 is an exploded view of the target adapter assembly.

FIG. 5 is an orthogonal view of an end cap assembly.

FIGS. 6-9 show examples of unbalanced magnet bars.

### DESCRIPTION

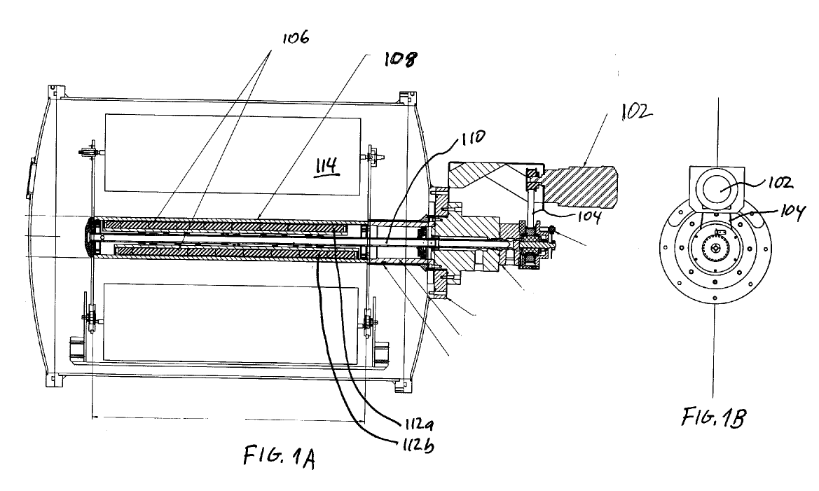

A primary embodiment of this invention is the ability to move the sputter plasma around the surface of the cylindrical target through rotation of the central magnet assembly. The sputtering direction from the target follows the internal magnet assembly rotation. For example, a cathode has been constructed and is depicted in the included drawings with a rotation mechanism. This particular example shows two magnet bars assembled 180 degrees apart. FIGS. 1A and 1B show a cross section and end view of the Cathode/Target Assembly. The rotation mechanism can comprise motor 102 driving a polytooth belt 104 that in turn rotates the central magnet assembly 106. Other devices could also be used. By controlling the motor 102 the magnet assembly 106 can be continuously rotated or rotated to a specific location and held in that position until it is desired to move the magnet assembly 106. In this way the magnet assembly location is completely programmable over time, thereby making it a controllable rotation mechanism. The magnet stacks 112a, 112b are components of the magnet assembly 106. The sputter deposition can be swept across the surface of the target 108 continuously or swept back and forth over a given angular range or even jumped from one surface of the target to another. It is this flexibility and programmable control that is a critical embodiment of this invention. The central drive shaft 110 also doubles as a water tube for cooling the magnet pack assembly 106 and inside of the target 108 with a constant flow of water. A work piece 114 is shown in a spaced relationship to the cathode inside a sputter chamber. The work piece may or may not rotate depending on the operator's choice for a particular sputtering task.

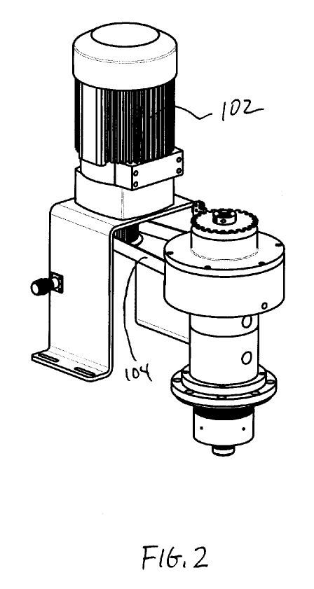

FIG. 2 shows an orthogonal view of the rotation mechanism drive assembly detailing water seals, bearings, electrical isolation of the power supply from the chamber, and mounting hardware interfaces.

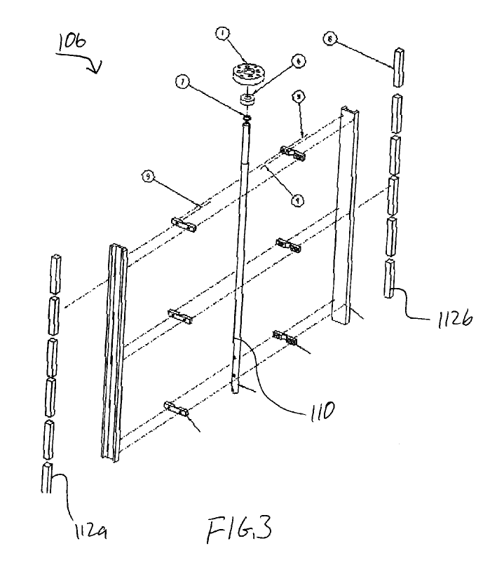

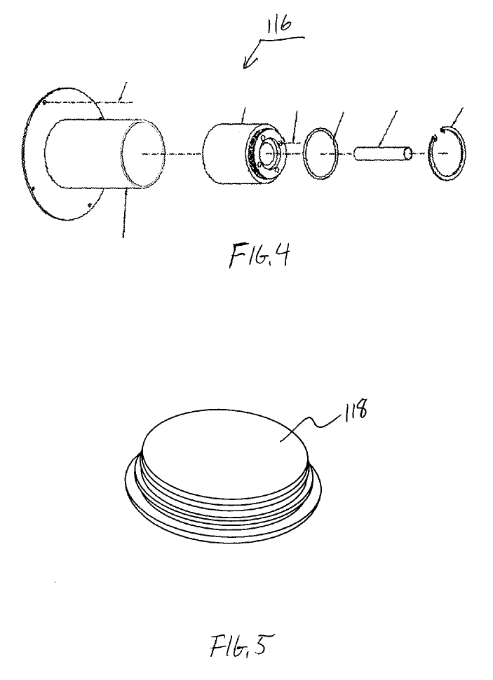

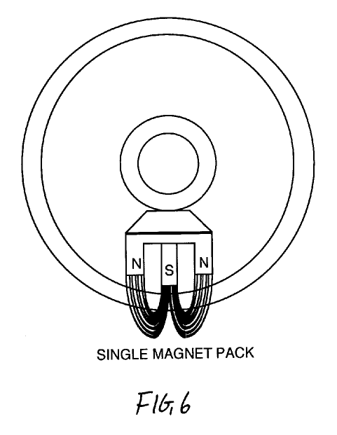

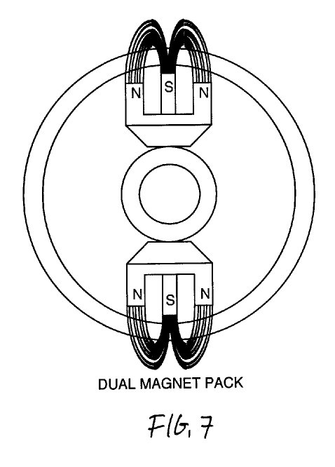

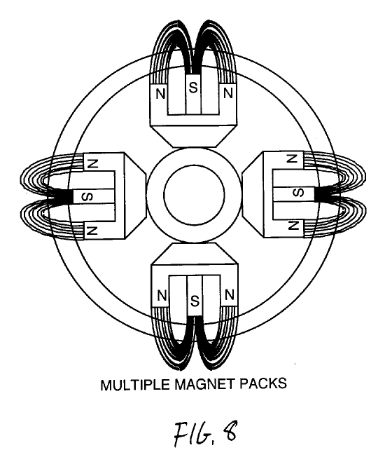

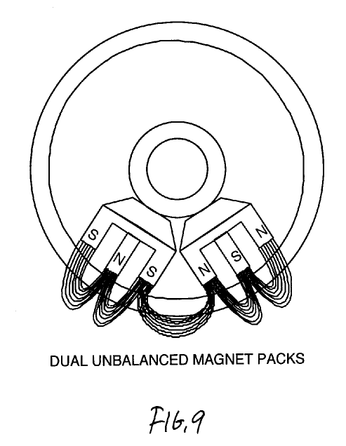

FIG. 3 shows an exploded view of the magnet bar assembly 106 for an application intended to rotate 360 degrees continuously. Two magnet bars 112a, 112b are affixed to the central water tube 110 to sputter the target cylinder at locations 180 degrees apart on the surface of the cylinder. This is not a requirement but an example of how rotating a magnet assembly within the target cylinder can be optimized to a particular coating application. Other configurations are shown in FIGS. 6-9.

FIGS. 4 and 5 show the target adapter 116 and end cap assembly 118 that mount the target in the cathode. A further embodiment of the invention is to offset the magnetic bars 112a, 112b along the longitudinal axis of the target cylinder. This reduces the magnetic field strength and associated target erosion at the ends of the cylinder, further contributing to longer target life and service intervals.

The capability to rotate the magnet assembly and change the direction of the sputtered material to any surface of the target allows further embodiments of this invention. The magnet pack can be rotated so that the sputtered material is directed at a shield assembly when burning in a target. In this case the target would also rotate to burn in the entire surface of the target.

A further embodiment is the ability to sweep the deposition area back and forth over a particular range of sputter angles. In this way parts moving past the cathode can be “followed” and the sputter direction change can place thicker coatings in certain areas or work together with another sweeping cathode to achieve desired thickness profiles. Uniformity can be optimized in this way or thicker coatings can be achieved in certain areas of the coating. A further embodiment of this invention is to replace linear planar cathodes with a rotating magnet assembly and rotating target to achieve higher uniformity coatings by sweeping the magnet assembly over a stationary or slowly moving part to be coated. By programming the sputter time at certain angular positions of the magnet assembly, surface coatings can be optimized.

As a further embodiment, the rotation of the magnet assembly can also be used to change coating profiles without changing the speed with which parts are moving past the source by following the parts angularly as they pass. The application possibilities are only examples of the ability to change coating characteristics through the use of a rotating magnet assembly within a cylindrical target that can be either stationary or rotating depending on the application.

As a further embodiment, FIGS. 6-9 depict unbalanced magnet bar assemblies which can be used to achieve unique process capabilities. The unbalanced zone between the two magnet bar assemblies can distribute the field across the two assemblies giving a broader sputter zone on the surface of the rotating or fixed cylindrical target. The strength of the magnetic fields can also be designed to optimize the sputter profile for particular applications.

The drawings depict the first implementation of this invention and do not limit the invention to this particular construction but serves as an example of how it can be implemented in a real world application. The use of a rotary target in many coating applications has not been feasible or even possible until this invention. By rotating the internal magnet assembly a rotating or fixed target can be sputtered in any direction around its central axis opening new applications and coating capabilities, some of which have been described above.

Although the preferred embodiments of the present invention have been described herein, the above description is merely illustrative. Further modification of the invention herein disclosed will occur to those skilled in the respective arts and all such modifications are deemed to be within the scope of the invention as defined by the appended claims.

We claim:

1. A sputtering cathode apparatus comprising:
a hollow cylindrical sputter target that is fixed or rotatable about its central axis; and
an internal magnet assembly that can be rotated axially within the sputter target.

2. The apparatus of claim 1, the magnet assembly comprising a plurality of magnet bars to induce sputtering at more than one radial direction.

3. The apparatus of claim 1, wherein the magnet assembly is unbalanced.

4. The apparatus of claim 1 wherein the magnet assembly is capable of continuously rotating.

5. The apparatus of claim 1 further comprising a mechanism for moving the internal magnet assembly to move the plasma on the target surface to optimize the coating of parts moving past the cathode.

6. The apparatus of claim 1 further comprising a mechanism for moving the internal magnet assembly to move the plasma on the target surface to optimize the coating of stationary parts in a vacuum chamber.

7. The apparatus of claim 1 wherein the magnet assembly is moved to a burn-in position prior to returning to its intended sputter position.

8. The apparatus of claim 1 having offset magnet bars to reduce target erosion at the ends of the target cylinder.

9. A sputtering cathode apparatus comprising:
a hollow cylindrical sputter target;
a magnet assembly aligned substantially coaxially within the sputter target; and
a rotation mechanism operatively coupled with the magnet assembly, whereby the magnet assembly can be rotated during the sputtering process.

10. The apparatus of claim 9, the magnet assembly comprising a collinear magnet stack offset from the axis of the magnet assembly.

11. The apparatus of claim 9, the magnet assembly comprising a plurality of collinear magnet stacks arranged asymmetrically about the axis of the magnet assembly.

12. The apparatus of claim 11, wherein the magnet stacks are offset from each other in the direction of the longitudinal axis, thereby reducing the magnetic field at the end of the stacks and thus reducing target erosion at the ends of the target cylinder.

13. The apparatus of claim 9, the magnet assembly comprising a plurality of collinear magnet stacks arranged symmetrically about the axis of the magnet assembly.

14. The apparatus of claim 13, wherein the magnet stacks are offset from each other in the direction of the longitudinal axis, thereby reducing the magnetic field at the end of the stacks and thus reducing target erosion at the ends of the target cylinder.

15. The apparatus of claim 9, wherein the rotation mechanism is a controllable rotation mechanism.

16. The apparatus of claim 9, the rotation mechanism comprising:
a motor; and
a polytooth belt operatively coupled with the motor.

17. A process for sputtering comprising the steps of:
controllably rotating a magnet assembly inside a target; and
sweeping sputter deposition across the surface of the target.

18. The process of claim 17, wherein the sweeping is continuous.

19. The process of claim 17, wherein the sweeping is swept back and forth over a given angular range.

20. The process of claim 17, further comprising the step of controllably rotating the hollow cylindrical target.
